(19) United States
(12) Patent Application Publication
(10) Pub. No.: US 2023/0217833 A1
(43) Pub. Date: Jul. 6, 2023

(54) VIBRATION APPARATUS AND APPARATUS INCLUDING THE SAME

(71) Applicant: LG Display Co., Ltd., Seoul (KR)

(72) Inventors: Sooyoun KIM, Paju-si (KR); Yong-Su HAM, Paju-si (KR); YongWoo LEE, Paju-si (KR); YuSeon KHO, Paju-si (KR); Jaeyoung LIM, Paju-si (KR)

(73) Assignee: LG Display Co., Ltd., Seoul (KR)

(21) Appl. No.: 17/980,553

(22) Filed: Nov. 4, 2022

(30) Foreign Application Priority Data
Jan. 1, 2022 (KR) 10-2022-0000009

(51) Int. Cl. H01L 41/053

(52) U.S. Cl. CPC H01L 41/053

(57) ABSTRACT

A vibration apparatus and an apparatus including the same are provided. The vibration apparatus includes a first vibration portion including a first material and a second vibration portion disposed adjacent to the first vibration portion, the second vibration portion including a second material. The apparatus including the vibration apparatus further includes a vibration object; a vibration generating apparatus at the vibration object; and a connection member between the vibration object and the vibration generating apparatus.

### CROSS-REFERENCE TO RELATED APPLICATIONS

This application claims the benefit of Korean Patent Application No. 10-2022-0000009 filed on Jan. 1, 2022, which is hereby incorporated by reference as if fully set forth herein.

### TECHNICAL FIELD

The present disclosure relates to a vibration apparatus and an apparatus including the same.

### DISCUSSION OF THE RELATED ART

An apparatus includes a separate speaker or a sound apparatus providing a sound. When a speaker is disposed in an apparatus, the speaker occupies a space, due to this, the design and spatial disposition of the apparatus are limited.

A speaker applied to the apparatus may be, for example, an actuator including a magnet and a coil. However, when an actuator is applied to the apparatus, a thickness thereof is thickened. Therefore, piezoelectric elements for realizing a thin thickness are attracting much attention.

Because piezoelectric elements have a fragile characteristic, the piezoelectric elements are easily damaged due to an external impact, and due to this, have a problem where reliability is low in sound reproduction. And, when a speaker such as a piezoelectric element or the like is applied to a flexible apparatus, there is a problem where damage occurs due to a fragile characteristic.

The description provided in the discussion of the related art section should not be assumed to be prior art merely because it is mentioned in or associated with that section. The discussion of the related art section may include information that describes one or more aspects of the subject technology, and the description in this section does not limit the invention.

### SUMMARY

Accordingly, the inventors of the present disclosure have recognized the problems described above as well as the problems and disadvantages of the related art, and have performed extensive research and experiments for implementing a vibration apparatus which may enhance the quality of a sound and a sound pressure level characteristic. Through the extensive research and experiments, the inventors have invented a new vibration apparatus and an apparatus including the same, which may enhance the quality of a sound.

Accordingly, embodiments of the present disclosure are directed to an apparatus that substantially obviates one or more of the problems due to limitations and disadvantages of the related art.

An aspect of the present disclosure is to provide a vibration apparatus and an apparatus including the same, in which a manufacturing method is simplified, mechanical strength is enhanced, and heat resistance is enhanced.

Accordingly, embodiments of the present disclosure are directed to an apparatus that substantially obviates one or more of the problems due to limitations and disadvantages of the related art.

Additional features and aspects of the disclosure will be set forth in the description that follows, and in part will be apparent from the present disclosure or may be learned by practice of the inventive concepts provided herein. Other features and aspects of the inventive concepts may be realized and attained by the description provided in the present disclosure, or derivable therefrom, and claims hereof as well as the appended drawings.

To achieve these and other aspects of the inventive concepts, as embodied and broadly described herein, a vibration apparatus comprises a first vibration portion including a first material, and a second vibration portion disposed adjacent to the first vibration portion, the second vibration portion including a second material.

In another aspect, a vibration apparatus comprises a vibration portion including a first vibration portion and a second vibration portion, a first electrode portion disposed at a first surface of the vibration portion, and a second electrode portion disposed at a second surface opposite to the first surface of the vibration portion. The first vibration portion includes a first material, the second vibration portion includes a second material, and the second vibration portion is disposed adjacent to the first vibration portion.

In a further aspect, an apparatus comprises a vibration object, a vibration generating apparatus at the vibration object, and a connection member between the vibration object and the vibration generating apparatus, the vibration generating apparatus comprises one or more vibration apparatus, the one or more vibration apparatus comprises a first vibration portion including a first material, and a second vibration portion disposed adjacent to the first vibration portion, the second vibration portion including a second material.

A vibration apparatus according to an embodiment of the present disclosure may include a composite of a material having a high mechanical quality factor and a material having a high piezoelectric constant, and thus, mechanical strength may be enhanced.

Comparing with a case where only a material having a high piezoelectric constant is used, the vibration apparatus according to an embodiment of the present disclosure may include a composite of a material having a high mechanical quality factor and a material having a high piezoelectric constant, and thus, conversion of mechanical loss may be reduced in converting electrical energy or the amount of heat may decrease, thereby preventing heat from occurring in the vibration apparatus.

The vibration apparatus according to an embodiment of the present disclosure may include a composite of a material having a high mechanical quality factor and a material having a high piezoelectric constant, and thus, a vibration corresponding to a low frequency may be implemented based on a piezoelectric constant and a haptic texture may be simultaneously implemented based on a high mechanical quality factor.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing description and the following description of the present disclosure are exemplary and explanatory, and are intended to provide further explanation of the disclosures as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure and together with the description serve to explain principles of the disclosure.

FIG. 1 illustrates a display apparatus according to an embodiment of the present disclosure.

FIG. 2 is a cross-sectional view taken along line I-I′ of FIG. 1.

FIG. 3 is another cross-sectional view taken along line I-I′ of FIG. 1.

FIG. 4 is a cross-sectional view illustrating a vibration member and a vibration apparatus at a rear surface of the vibration member according to an embodiment of the present disclosure.

FIG. 5 is a cross-sectional view illustrating a vibration member and a vibration apparatus at a rear surface of the vibration member according to another embodiment of the present disclosure.

FIG. 6 illustrates a vibration portion according to an embodiment of the present disclosure.

FIG. 7A illustrates a vibration portion according to another embodiment of the present disclosure.

FIG. 7B illustrates a vibration portion according to another embodiment of the present disclosure.

FIG. 8A is a cross-sectional view illustrating a vibration member and a vibration apparatus at a rear surface of the vibration member according to an embodiment of the present disclosure.

FIG. 8B is a cross-sectional view illustrating a vibration member and a vibration apparatus at a rear surface of the vibration member according to an embodiment of the present disclosure.

FIG. 8C is a cross-sectional view illustrating a vibration member and a vibration apparatus at a rear surface of the vibration member according to an embodiment of the present disclosure.

FIG. 8D is a cross-sectional view illustrating a vibration member and a vibration apparatus at a rear surface of the vibration member according to an embodiment of the present disclosure.

FIG. 9 is a cross-sectional view illustrating a vibration member and a vibration apparatus at a rear surface of the vibration member according to another embodiment of the present disclosure.

FIGS. 10A to 10D are graphs of a permittivity, an electromechanical coupling coefficient, a mechanical quality factor, and a piezoelectric constant of a vibration apparatus according to an embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and convenience.

### DETAILED DESCRIPTION

Reference is now made in detail to embodiments of the present disclosure, examples of which may be illustrated in the accompanying drawings. In the following description, when a detailed description of well-known functions or configurations related to this document is determined to unnecessarily obscure aspects of the present disclosure, the detailed description thereof may be omitted for brevity. The progression of processing steps and/or operations described is an example; however, the sequence of steps and/or operations is not limited to that set forth herein and may be changed, with the exception of steps and/or operations necessarily occurring in a particular order.

Unless stated otherwise, like reference numerals may refer to like elements throughout even when they are shown in different drawings. In one or more aspects, identical elements (or elements with identical names) in different drawings may have the same or substantially the same functions and properties unless stated otherwise. Names of the respective elements used in the following explanations are selected only for convenience of writing the specification and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are provided so that this disclosure is thorough and complete, and fully conveys the scope of the present disclosure to those skilled in the art.

The shapes, sizes, areas, ratios, angles, numbers, and the like disclosed in the drawings for describing embodiments of the present disclosure are merely examples, and thus, the present disclosure is not limited to the illustrated details.

When the term “comprise,” “have,” “include,” “contain,” “constitute,” “make up of,” “formed of,” and the like is used, one or more other elements may be added unless a term, “only” or the like is used. The terms used in the present disclosure are merely used in order to describe particular embodiments, and are not intended to limit the scope of the present disclosure. The terms used herein are merely used in order to describe example embodiments, and are not intended to limit the scope of the present disclosure. The terms of a singular form may include plural forms unless referred to the contrary. The word “exemplary” is used to mean serving as an example or illustration. Embodiments are example embodiments. Aspects are example aspects. Any implementation described herein as an “example” is not necessarily to be construed as preferred or advantageous over other implementations.

In one or more aspects, an element, feature, or corresponding information (e.g., a level, range, dimension, size, or the like) is construed as including an error or tolerance range even where no explicit description is provided. An error or tolerance range may be caused by various factors (e.g., process factors, internal or external impact, noise, or the like). Further, the term “may” encompasses all the meanings of the term “can.”

In describing a positional relationship, where the positional relation between two parts is described as, for example, “on,” “over,” “under,” “above,” “below,” “beneath,” “near,” “close to,” “adjacent to,” “beside,” “next to,” or the like, one or more other portions may be located between two other portions unless a more limiting term, such as “immediate(ly),” “direct(ly),” or “close(ly),” is used. In the description of embodiments, when a structure is described as being positioned “on or above” or “under or below” another structure, this description should be construed as including a case in which the structures contact each other as well as a case in which a third structure is disposed therebetween.

In describing a temporal relationship, when the temporal order is described as “after,” “subsequent,” “next,” “before,” “prior to,” or the like a case that is not consecutive or not sequential may be included unless a more limiting term, such as “just,” “immediate(ly),” or “direct(ly),” is used.

It is understood that, although the term “first,” “second,” “A,” “B,” “(a),” “(b),” or the like may be used herein to describe various elements, these elements should not be limited by these terms. These terms are only used to distinguish one element from another. For example, a first element could be a second element, and, similarly, a second element could be a first element, without departing from the scope of the present disclosure. Furthermore, the first element, the second element, and the like may be arbitrarily named according to the convenience of those skilled in the art without departing from the scope of the present disclosure. The terms “first,” “second,” and the like may be used to distinguish components from each other, but the functions or structures of the components are not limited by ordinal numbers or component names in front of the components.

In describing elements of the present disclosure, the term “first,” “second,” “A,” “B,” “(a),” “(b),” or the like may be used. These terms are intended to identify the corresponding element(s) from the other element(s), and these are not used to define the essence, basis, order, or number of the elements.

For the expression that an element or layer is “connected,” “coupled,” or “adhered” to another element or layer, the element or layer can not only be directly connected, coupled, or adhered to another element or layer, but also be indirectly connected, coupled, or adhered to another element or layer with one or more intervening elements or layers disposed or interposed between the elements or layers, unless otherwise specified.

The term “at least one” should be understood as including any and all combinations of one or more of the associated listed items. For example, the meaning of “at least one of a first item, a second item, and a third item” denotes the combination of items proposed from two or more of the first item, the second item, and the third item as well as only one of the first item, the second item, or the third item.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C. Furthermore, an expression “element A/element B” may be understood as element A and/or element B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

Features of various embodiments of the present disclosure may be partially or wholly coupled to or combined with each other, and may be variously inter-operated, linked or driven together. The embodiments of the present disclosure may be carried out independently from each other, or may be carried out together in a co-dependent or related relationship. In one or more aspects, the components of each apparatus according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

Hereinafter, embodiments of the present disclosure are described in detail with reference to the accompanying drawings. With respect to reference numerals to elements of each of the drawings, although the same elements may be illustrated in other drawings, like reference numerals may refer to like elements unless stated otherwise. In addition, for convenience of description, a scale, dimension, size, and thickness of each of the elements illustrated in the accompanying drawings may differ from an actual scale, dimension, size, and thickness, and thus, embodiments of the present disclosure are not limited to a scale, dimension, size, and thickness illustrated in the drawings.

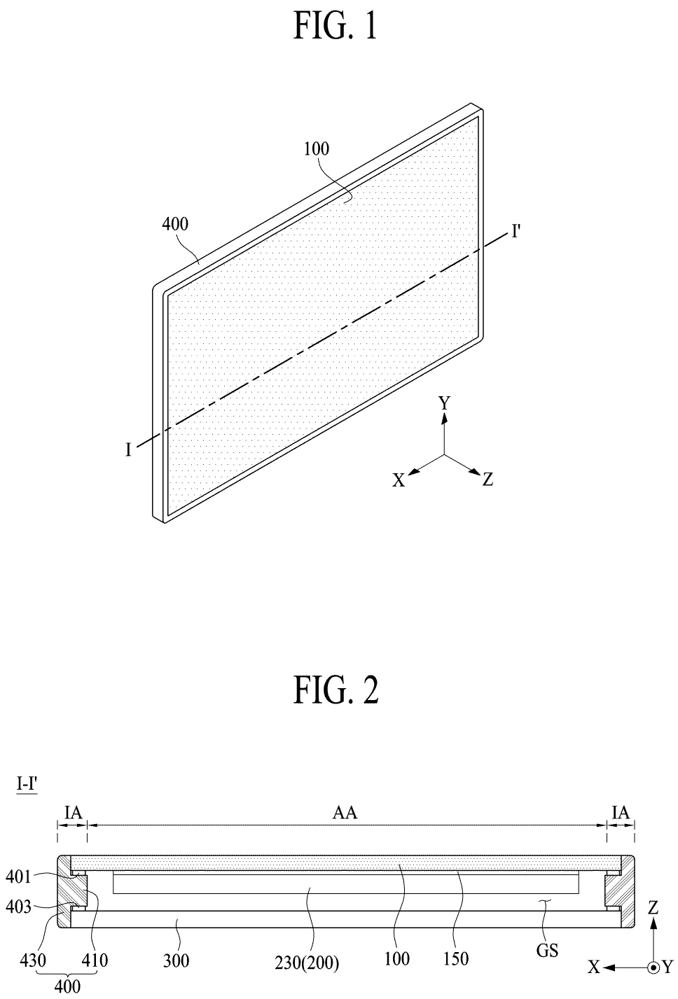

FIG. 1 illustrates a display apparatus according to an embodiment of the present disclosure. FIG. 2 is a cross-sectional view taken along line I-I′ of FIG. 1.

With reference to FIGS. 1 and 2, an apparatus according to an embodiment of the present disclosure may include a vibration member and a vibration apparatus 200 disposed at a rear surface (or a backside surface) of the vibration member. For example, the vibration member may output a sound based on a vibration of the vibration apparatus 200. For example, the vibration member may be a vibration object, a display panel, a vibration plate, or a front member, but embodiments of the present disclosure are not limited thereto.

For example, the vibration member or the vibration object may include one or more among a display panel including a plurality of pixels configured to display an image, a screen panel on which an image is projected from a display apparatus, a lighting panel, a signage panel, a vehicular interior material, a vehicular glass window, a vehicular exterior material, a building ceiling material, a building interior material, a building glass window, an aircraft interior material, an aircraft glass window, wood, plastic, glass, metal, cloth, fiber, paper, rubber, leather, carbon, and a mirror.

Hereinafter, an example where the vibration member is a display panel will be described.

With reference to FIGS. 1 and 2, an apparatus according to an embodiment of the present disclosure may include a display panel 100 to display an image, and a vibration apparatus 200 which vibrates the display panel 100 at a rear surface (or a backside surface) of the display panel 100.

The display panel 100 may display an electronic image, a digital image, a still image, or a video image, or the like. For example, the display panel 100 may output light to display an image. The display panel 100 may be a curved display panel, or may be any type of display panel, such as a liquid crystal display panel, an organic light-emitting display panel, a quantum dot light-emitting display panel, a micro light-emitting diode display panel, and an electrophoresis display panel. The display panel 100 may be a flexible display panel. For example, the display panel 100 may be a flexible light emitting display panel, a flexible electrophoretic display panel, a flexible electro-wetting display panel, a flexible micro light emitting diode display panel, or a flexible quantum dot light emitting display panel, but embodiments of the present disclosure are not limited thereto.

The display panel 100 according to an embodiment of the present disclosure may include a display area AA for displaying an image according to driving of the plurality of pixels. Also, the display panel 100 may include a non-display area IA surrounding the display area AA, but embodiment of the present disclosure is not limited thereto.

The display panel 100 according to an embodiment of the present disclosure may be configured to display an image in a type such as a top emission type, a bottom emission type, a dual emission type, or the like according to a structure of the pixel array layer including a plurality of pixels having an anode electrode, a cathode electrode, and a light emitting device. In the top emission type, an image may be displayed by outputting visible light generated from the pixel array layer to the forward region of a base substrate. In the bottom emission type, an image may be displayed by outputting visible light generated from the pixel array layer to the backward region of the base substrate.

The display panel 100 according to an embodiment of the present disclosure may include a pixel array part disposed on the display area AA on a substrate. The pixel array part may include a plurality of pixels which display an image based on a signal supplied through signal lines. The signal lines may include a gate line, a data line, a pixel driving power line, or the like, but embodiments of the present disclosure are not limited thereto.

Each of the plurality of pixels may include a pixel circuit layer including a driving thin film transistor (TFT) provided in a pixel area configured by a plurality of gate lines and/or a plurality of data lines, an anode electrode electrically connected to the driving TFT, a light emitting device formed over the anode electrode, and a cathode electrode electrically connected to the light emitting device.

The driving TFT may be configured at a transistor region of each pixel area provided at a substrate. The driving TFT may include a gate electrode, a gate insulation layer, a semiconductor layer, a source electrode, and a drain electrode. The semiconductor layer of the driving TFT may include silicon such as amorphous silicon (a-Si), polysilicon (poly-Si), or low temperature poly-Si or may include oxide such as indium-gallium-zinc-oxide (IGZO), but embodiments of the present disclosure are not limited thereto.

The anode electrode (or a pixel electrode) may be provided at an opening region disposed at each pixel area and may be electrically connected to the driving TFT.

A light emitting device according to an embodiment may include an organic light emitting device layer formed on an anode electrode. The organic light emitting device layer may be implemented to emit light having the same color (for example, white light) for each pixel, or may be implemented to emit light having a different color (for example, red light, green light, or blue light) for each pixel. A cathode electrode (or a common electrode) may be connected to the organic light emitting device layer provided in each pixel area in common. For example, the organic light emitting device layer may have a stack structure including a single structure or two or more structures including the same color for each pixel. As another embodiment of the present disclosure, the organic light emitting device layer may have a stack structure including two or more structures including one or more different colors for each pixel. The two or more structures including the one or more different colors may be configured with one or more of blue, red, yellow-green, and green or a combination thereof, but embodiments of the present disclosure are not limited thereto. An example of the combination may include blue and red, red and yellow-green, red and green, red/yellow-green/green, or the like, but embodiments of the present disclosure are not limited thereto. Also, regardless of a stack order thereof, the present disclosure may be applied. The stack structure including two or more structures having the same color or one or more different colors may further include a charge generating layer between the two or more structures. The charge generating layer may have a PN junction structure and may include an N-type charge generating layer and a P-type charge generating layer.

The light emitting device according to another embodiment of the present disclosure may include a micro light emitting diode device electrically connected to each of an anode electrode and a cathode electrode. The micro light emitting diode device may be a light emitting diode implemented as an integrated circuit (IC) or chip type. The micro light emitting diode device may include a first terminal electrically connected to the anode electrode and a second terminal electrically connected to the cathode electrode. The cathode electrode may be connected to the second terminal of the micro light emitting diode device provided in each pixel area in common.

An encapsulation part may be formed on the substrate to surround the pixel array part, thereby preventing oxygen or water from penetrating into the light emitting device of the pixel array part. The encapsulation part according to an embodiment of the present disclosure may be formed in a multi-layer structure where an organic material layer and an inorganic material layer are alternately stacked, but embodiment of the present disclosure is not limited thereto. The inorganic material layer may prevent oxygen or water from penetrating into the light emitting device of the pixel array part. The organic material layer may be formed to have a thickness which is relatively thicker than the inorganic material layer, so as to cover particles occurring in a manufacturing process. For example, the encapsulation part may include a first inorganic layer, an organic layer over the first inorganic layer, and a second inorganic layer over the organic layer. The organic layer may be a particle cover layer, but embodiments of the present disclosure are not limited thereto. The touch panel may be disposed over the encapsulation part, or may be disposed at a rear surface of the pixel array part.

The display panel 100 according to an embodiment of the present disclosure may include a first substrate, a second substrate, and a liquid crystal layer. The first substrate may be an upper substrate or a thin film transistor (TFT) array substrate. For example, the first substrate may include a pixel array (or a display part or a display area) including a plurality of pixels which are respectively provided in a plurality of pixel areas defined by intersections between a plurality of gate lines and/or a plurality of data lines. Each of the plurality of pixels may include a TFT connected to a gate line and/or a data line, a pixel electrode connected to the TFT, and a common electrode which is provided adjacent to the pixel electrode and is supplied with a common voltage.

The first substrate may further include a pad part provided at a first periphery (or a first non-display part) and a gate driving circuit provided at a second periphery (or a second non-display part).

The pad part may supply a signal, supplied from the outside, to the pixel array and/or the gate driving circuit. For example, the pad part may include a plurality of data pads connected to a plurality of data lines through a plurality of data link lines and/or a plurality of gate input pads connected to the gate driving circuit through a gate control signal line. For example, a size of the first substrate may be greater than the second substrate, but embodiments of the present disclosure are not limited thereto.

The gate driving circuit may be embedded (or integrated) into the second periphery of the first substrate so as to be connected to the plurality of gate lines. For example, the gate driving circuit may be implemented as a shift register including a transistor, which is formed through the same process as the TFT provided at the pixel area. The gate driving circuit according to another embodiment of the present disclosure may not be embedded into the first substrate and may be included in a panel driving circuit as an integrated circuit (IC) type.

The second substrate may be a lower substrate or a color filter array substrate. For example, the second substrate may include a pixel opening pattern including an opening area overlapping with the pixel area formed in the first substrate, and a color filter layer formed at the opening area. The second substrate may have a size which is smaller than the first substrate, but embodiments of the present disclosure are not limited thereto. For example, the second substrate may overlap a remaining portion, other than the first periphery, of the upper substrate. The second substrate may be attached to a remaining portion, other than the first periphery, of the first substrate with a liquid crystal layer therebetween using a sealant.

The liquid crystal layer may be disposed between the first substrate and the second substrate. The liquid crystal layer may include a liquid crystal including liquid crystal molecules where an alignment direction thereof is changed based on an electric field generated by the common voltage and a data voltage applied to a pixel electrode for each pixel.

A second polarization member may be disposed at a lower surface of the second substrate and may polarize light which is incident from the backlight and travels to the liquid crystal layer. A first polarization member may be disposed at an upper surface of the first substrate and may polarize light which passes through the first substrate and is output to the outside.

The display panel 100 according to an embodiment of the present disclosure may drive the liquid crystal layer based on an electric field which is generated in each pixel by the data voltage and the common voltage applied to each pixel, and thus, may display an image based on light passing through the liquid crystal layer.

In display panel 100 according to another embodiment of the present disclosure, the first substrate may be implemented as the color filter array substrate, and the second substrate may be implemented as the TFT array substrate. For example, the display panel 100 according to another embodiment of the present disclosure may have a type where an upper portion and a lower portion of the display panel according to an embodiment of the present disclosure are reversed therebetween. For example, a pad part of the display panel according to another embodiment of the present disclosure may be covered by a separate mechanism or a separate structure.

The display panel 100 according to another embodiment of the present disclosure may include a bending portion that may be bent or curved to have a curved shape or a certain curvature radius.

The bending portion of the display panel 100 may be implemented in at least one or more of one periphery and the other periphery which are parallel to each other in the display panel 100. The one periphery and/or the other periphery, where the bending portion is implemented, of the display panel 100 may include only the non-display area IA, or may include a periphery of the display area AA and the non-display area IA. The display panel including the bending portion implemented by bending of the non-display area IA may have a one-side bezel bending structure or a both-side bezel bending structure. Moreover, the display panel 100 including the bending portion implemented by bending of the periphery of the display area AA and the non-display area IA may have a one-side active bending structure or a both-side active bending structure.

The vibration apparatus 200 may vibrate the display panel 100 at the rear surface of the display panel 100, thereby providing a sound and/or a haptic feedback based on the vibration of the display panel 100 to a user. The vibration apparatus 200 may be implemented at the rear surface of the display panel 100 to directly vibrate the display panel 100.

According to an embodiment of the present disclosure, the vibration apparatus 200 may vibrate according to a vibration driving signal synchronized with an image displayed on the display panel that is the display panel 100 to vibrate the display panel. As another embodiment of the present disclosure, the vibration apparatus 200 may vibrate according to a haptic feedback signal (or a tactile feedback signal) synchronized with a user touch applied to a touch panel (or a touch sensor layer) which is disposed at the display panel 100 or embedded into the display panel and may vibrate the display panel 100. Accordingly, the display panel 100 may vibrate based on a vibration of the vibration apparatus 200 to provide a user (or a viewer) with at least one or more of a sound and a haptic feedback.

The vibration apparatus 200 according to an embodiment of the present disclosure may be implemented to have a size corresponding to the display area AA of the display panel 100. A size of the vibration apparatus 200 may be 0.9 to 1.1 times a size of the display area AA, but embodiments of the present disclosure are not limited thereto. For example, a size of the vibration apparatus 200 may be the same as or smaller than the size of the display area AA. For example, a size of the vibration apparatus 200 may be the same as or approximately same as the display area AA of the display panel 100, and thus, the vibration apparatus 200 may cover a most region of the display panel 100 and a vibration generated by the vibration apparatus 200 may vibrate a whole portion of the display panel 100, and thus, localization of a sound may be high, and satisfaction of a user may be improved. Also, a contact area (or panel coverage) between the display panel 100 and the vibration apparatus 200 may increase, and thus, a vibration region of the display panel 100 may increase, thereby improving a sound of a middle-low-pitched sound band generated based on a vibration of the display panel 100. Also, a vibration apparatus 200 applied to a large-sized display apparatus may vibrate the whole display panel 100 having a large size (or a large area), and thus, localization of a sound based on a vibration of the display panel 100 may be further enhanced, thereby realizing an improved sound effect. Therefore, the vibration apparatus 200 according to an embodiment of the present disclosure may be disposed at the rear surface of the display panel 100 to sufficiently vibrate the display panel 100 in a vertical direction (or front-to-rear direction), thereby outputting a sound to a forward region in front of the apparatus or the display apparatus.

The vibration apparatus 200 according to an embodiment of the present disclosure may be implemented as a film-type. Since the vibration apparatus 200 may be implemented as a film-type, it may have a thickness which is thinner than the display panel 100, and thus, an increase in the thickness of the display apparatus may be minimized due to the arrangement of the vibration apparatus 200. For example, the vibration apparatus 200 may use the display panel 100 as a sound vibration plate. For example, the vibration apparatus 200 may be referred to as a sound generating module, a sound generating apparatus, a film actuator, a film-type piezoelectric composite actuator, a film speaker, a film-type piezoelectric speaker, a film-type piezoelectric composite speaker, or the like, but embodiments of the present disclosure are not limited thereto. For example, the display panel 100 may be a display panel including a pixel configured to display an image or a screen panel on which an image is to be projected from a display apparatus, but embodiments of the present disclosure are not limited thereto. As another embodiment of the present disclosure, the vibration apparatus 200 may not be disposed at the rear surface of the display panel 100 and may be applied to a vibration object instead of the display panel 100. For example, the vibration object may include one or more of a non-display panel, a vibration plate, wood, plastic, glass, cloth, a vehicle interior material, a vehicle glass window, a building ceiling material, a building glass window, an aircraft interior material, and an aircraft glass window, but embodiments of the present disclosure are not limited thereto. For example, the non-display panel may be a light emitting diode lighting panel (or apparatus), an organic light emitting lighting panel (or apparatus), or an inorganic light emitting lighting panel (or apparatus, or the like, but embodiments of the present disclosure are not limited thereto. In this case, the vibration object may be applied as a vibration plate, and the vibration apparatus 200 may vibrate the vibration object to output a sound.

The vibration apparatus 200 according to an embodiment of the present disclosure may comprise at least one vibration generator 230.

The vibration generator 230 may include a piezoelectric structure (a vibration portion or a piezoelectric vibration portion) including piezoelectric ceramic having a piezoelectric characteristic, but embodiments of the present disclosure are not limited thereto. For example, the vibration generator 230 according to an embodiment of the present disclosure may include piezoelectric ceramic having a perovskite crystalline structure, and thus, may vibrate (or mechanically displace or drive) in response to an electrical signal applied from the outside. For example, when a vibration driving signal (or a voice signal) is applied, the vibration generator 230 may alternately repeat contraction and expansion, based on an inverse piezoelectric effect of the piezoelectric structure material (the vibration portion or the piezoelectric vibration portion), and thus, may be displaced (or vibrated or driven) in the same direction, based on a bending phenomenon where a bending direction is alternately changed, thereby increasing or maximizing a displacement amount (or a bending force) or an amplitude displacement of the vibration apparatus 200 or/and the display panel 100.

Alternatively, in the vibration apparatus 200 according to another embodiment of the present disclosure, a plurality of vibration generators may overlap one another or may be stacked to be displaced (or vibrated or driven) in the same direction. For example, each of the plurality of vibration generators may contract or expand in the same driving direction (or displacement direction) based on a vibration driving signal in a state where the plurality of vibration generators overlap one another or are stacked, and thus, a displacement amount (or a bending force) or an amplitude displacement may increase or may be maximized. Therefore, because the plurality of vibration generators increases (or maximizes) a displacement amount (or a bending force) or an amplitude displacement of the display panel 100, a sound pressure level characteristic of a sound and a sound characteristic of a middle-low pitched sound band generated based on a vibration of the display panel 100 may be enhanced. For example, because the plurality of vibration generators are implemented to overlap one another or to be stacked in the same driving direction, a driving force of each of the plurality of vibration generators may increase or may be maximized, and thus, a sound pressure level characteristic generated by the display panel 100 based on vibrations of the plurality of vibration generators may be enhanced.

The display apparatus according to an embodiment of the present disclosure may further include a connection member 150 disposed between the vibration generator 230 and the display panel 100.

According to an embodiment of the present disclosure, the connection member 150 may include at least one base member and may include an adhesive layer attached on one surface or both surfaces of the base member.

According to an embodiment of the present disclosure, the connection member 150 according to an embodiment of the present disclosure may include a material including an adhesive layer which is good in adhesive force or attaching force with respect to the vibration generator 230. For example, the connection member 150 may include a foam pad, a double-sided tape, a double-sided foam tape, or an adhesive, or the like, but embodiments of the present disclosure are not limited thereto. For example, the adhesive layer of the connection member 150 may include epoxy-based polymer, acrylic-based polymer, silicone-based polymer, or urethane-based polymer, but embodiments of the present disclosure are not limited thereto.

The connection member 150 according to another embodiment of the present disclosure may include one or more of a thermo-curable adhesive, a photocurable adhesive, and a thermal bonding adhesive. For example, the connection member 150 may include the thermal bonding adhesive. The thermal bonding adhesive may be a heat-active type or a thermo-curable type. For example, the connection member 150 including the thermal bonding adhesive may attach or couple the vibration generator 230 and the display panel 100 to each other by heat and pressure.

The connection member 150 may be disposed between the rear surface (or a backside surface) of the display panel 100 and the vibration apparatus 200, and may connect or couple the vibration apparatus 200 to the rear surface of the display panel 100. For example, the vibration apparatus 200 may be connected or coupled to the rear surface of the display panel 100 by the connection member 150, and thus, may be supported by or disposed at the rear surface of the display panel 100.

The connection member 150 according to an embodiment of the present disclosure may include a material including an adhesive layer which is good in adhesive force or attaching force with respect to each of the rear surface of the display panel 100 and the vibration apparatus 200. For example, the connection member 150 may include a foam pad, a double-sided tape, a double-sided foam tape, an adhesive, or the like, but embodiments of the present disclosure are not limited thereto. For example, the adhesive layer of the connection member 150 may include epoxy-based polymer, acrylic-based polymer, silicone-based polymer, or urethane-based polymer, but embodiments of the present disclosure are not limited thereto. For example, the adhesive layer of the connection member 150 may include an acrylic-based material which is relatively better in adhesive force and hardness of acrylic and urethane. Accordingly, a vibration of the vibration apparatus 200 may be transferred to the display panel 100 well.

The connection member 150 according to another embodiment of the present disclosure may further include a hollow portion provided between the display panel 100 and the vibration apparatus 200. The hollow portion of the connection member 150 may provide an air gap between the display panel 100 and the vibration apparatus 200. Due to the air gap, a sound wave (or a sound pressure) based on a vibration of the vibration apparatus 200 may not be dispersed by the connection member 150, and may concentrate on the display panel 100. Thus, the loss of a vibration caused by the connection member 150 may be minimized, thereby increasing a sound pressure level characteristic of a sound generated based on a vibration of the display panel 100.

The apparatus according to an embodiment of the present disclosure may further include a supporting member 300 disposed at a rear surface of the display panel 100.

The supporting member 300 may cover a rear surface of the display panel 100. For example, the supporting member 300 may cover a whole rear surface of the display panel 100 with a gap space GS therebetween. The supporting member 300 may include at least one or more material of a glass material, a metal material, and a plastic material. For example, the supporting member 300 may be a rear surface structure or a set structure. For example, the supporting member 300 may be referred to as the other term such as a cover bottom, a plate bottom, a back cover, a base frame, a metal frame, a metal chassis, a chassis base, m-chassis, or the like. For example, the supporting member 300 may be implemented as an arbitrary type frame or a plate-shaped structure disposed at a rear surface of the display panel 100.

The apparatus according to an embodiment of the present disclosure may further include a middle frame 400.

The middle frame 400 may be disposed between a rear periphery of display panel 100 and a front periphery of the supporting member 300. The middle frame 400 may support one or more of the rear periphery of the display panel 100 and the front periphery of the supporting member 300 and may surround one or more of side surfaces of each of the display panel 100 and the supporting member 300. The middle frame 400 may provide a gap space GS between the display panel 100 and the supporting member 300. The middle frame 400 may be referred to as a middle cabinet, a middle cover, or a middle chassis, or the like, but embodiments of the present disclosure are not limited thereto.

The middle frame 400 according to an embodiment of the present disclosure may include a first supporting portion 410 and a second supporting portion 430.

The first supporting portion 410 may be disposed between the rear periphery of the display panel 100 and the front periphery of the supporting member 300, and thus, may provide a gap space GS between the display panel 100 and the supporting member 300. A front surface of the first supporting portion 410 may be coupled or connected to the rear periphery of the display panel 100 by a first frame connection member 401. A rear surface of the first supporting portion 410 may be coupled or connected to the front periphery of the supporting member 300 by a second frame connection member 403. For example, the first supporting portion 410 may have a single picture frame structure having a square shape or a frame structure having a plurality of divided bar shapes, but embodiments of the present disclosure are not limited thereto.

The second supporting portion 430 may be vertically coupled to an outer surface of the first supporting portion 410 in parallel with a thickness direction Z of the apparatus. The second supporting portion 430 may surround one or more of an outer surface of the display panel 100 and an outer surface of the supporting member 300, thereby protecting the outer surface of each of the display panel 100 and the supporting member 300. The first supporting portion 410 may protrude from an inner surface of the second supporting portion 430 toward the gap space GS between the display panel 100 and the support member 300.

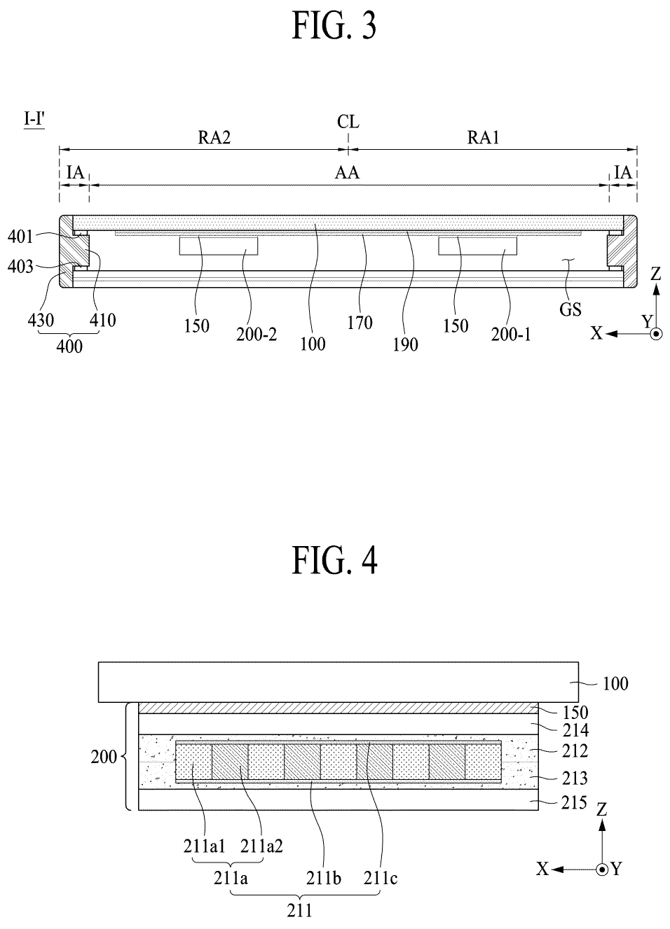

FIG. 3 is another cross-sectional view taken along line I-I′ illustrated in FIG. 1. FIG. 3 illustrates an embodiment implemented by modifying a vibration apparatus illustrated in FIG. 2. Therefore, in the following description, repetitive descriptions of elements other than the vibration apparatus and elements relevant thereto may be omitted or will be briefly given.

With reference to FIGS. 1 and 3, in the apparatus according to another embodiment of the present disclosure, a display panel 100 may include a first rear region RA1 and a second rear region RA2. For example, the first rear region RA1 may be a right rear region, and the second rear region RA2 may be a left rear region. The first and second rear regions RA1 and RA2 may be a left-right symmetrical with respect to a center line CL of the display panel 100 in a first direction X, but embodiments of the present disclosure are not limited thereto. For example, each of the first and second rear regions RA1 and RA2 may overlap the display area AA of the display panel 100.

The vibration apparatus (or a vibration generating apparatus) 200 according to another embodiment of the present disclosure may include a first vibration generating apparatus 200-1 and a second vibration generating apparatus 200-2.

The first vibration generating apparatus 200-1 may be disposed at the first rear region RA1 of the display panel 100. A size of the first vibration generating apparatus 200-1 may have the same size as the first rear area RA1 of the display panel 100 or may have a size smaller than the first rear area RA1 of the display panel 100 based on a characteristic of a first sound or a sound characteristic needed for the apparatus. For example, the first vibration generating apparatus 200-1 may be disposed close to a center or a periphery within the first rear region RA1 of the display panel 100 with respect to the first direction X.

According to an embodiment of the present disclosure, the first vibration generating apparatus 200-1 may vibrate the first rear region RA1 of the display panel 100, and thus, may generate the first sound of at least one of a first vibration sound, a first orientation vibration sound, and a first haptic feedback. For example, the first vibration generating apparatus 200-1 may directly vibrate the first rear region RA1 of the display panel 100, and thus, may generate the first sound in the first rear region RA1 of the display panel 100. For example, the first sound may be a right sound.

The second vibration generating apparatus 200-2 may be disposed at the second rear region RA2 of the display panel 100. A size of the second vibration generating apparatus 200-2 may have the same size as the second rear area RA2 of the display panel 100 or may have a size smaller than the second rear area RA2 of the display panel 100 based on a characteristic of the second sound or the sound characteristic needed for the apparatus. For example, the second vibration generating apparatus 200-2 may be disposed close to a center or a periphery within the second rear region RA2 of the display panel 100 with respect to the first direction X.

According to an embodiment of the present disclosure, the second vibration generating apparatus 200-2 may vibrate the second rear region RA2 of the display panel 100, and thus, may generate the second sound of at least one of a second vibration sound, a second orientation vibration sound, and a second haptic feedback. For example, the second vibration generating apparatus 200-2 may directly vibrate the second rear region RA2 of the display panel 100, and thus, may generate the second sound in the second rear region RA2 of the display panel 100. For example, the second sound may be a left sound.

The first and second vibration generating apparatuses 200-1 and 200-2 may have the same size or different sizes to each other based on a sound characteristic of left and right sounds and/or a sound characteristic of the apparatus. And, the first and second vibration generating apparatuses 200-1 and 200-2 may be disposed in a left-right symmetrical structure or a left-right asymmetrical structure with respect to the center line CL of the display panel 100.

Each of the first vibration generating apparatus 200-1 and the second vibration generating apparatus 200-2 may include the vibration apparatus described above with reference to FIGS. 1 and 2, and thus, their repetitive descriptions may be omitted.

Each of the first vibration generating apparatus 200-1 and the second vibration generating apparatus 200-2 may disposed at the rear surface of the display panel 100 by the connection member 150. The connection member 150 may be substantially the same as the connection member 150 described above with reference to FIG. 2, and thus, the repetitive description thereof may be omitted.

The apparatus (or a display apparatus) according to another embodiment of the present disclosure may output a left sound and a right sound to a forward region in front of the display panel 100 through the first vibration generating apparatus 200-1 and the second vibration generating apparatus 200-2, may concentrate or focus in a specific direction a sound generated based on a vibration of each of the first vibration generating apparatus 200-1 and the second vibration generating apparatus 200-2, and thus, may implement a user’s privacy protection function of allowing a sound not to be listened in a periphery region (or an inaudible region) other than a region (or an audible region) in a specific direction.

The apparatus according to another embodiment of the present disclosure may further include a plate 170 which is disposed between the display panel 100 and the vibration apparatus 200.

The plate 170 may have the same shape and size as the rear surface of the display panel 100, or may have the same shape and size as the vibration apparatus 200. As another embodiment of the present disclosure, the plate 170 may have a size different from the display panel 100. For example, the plate 170 may be smaller than the size of the display panel 100. As another embodiment of the present disclosure, the plate 170 may have a size different from the vibration apparatus 200. For example, the plate 170 may be greater or smaller than the size of the vibration apparatus 200. The vibration apparatus 200 may be the same as or smaller than the size of the display panel 100.

The plate 170 may be coupled or connected to the rear surface of the display panel 100 by a plate coupling member (or a coupling member or a connection member) 190. Thus, the vibration apparatus 200 may be connected or coupled to a rear surface of the plate 170 by the connection member 150, and thus, may be supported by or hung at the rear surface of the plate 170.

┬he plate 170 according to an embodiment of the present disclosure may include a plurality of opening portions. The plurality of opening portions may be configured to have a predetermined size and a predetermined interval. For example, the plurality of opening portions may be formed along a first direction X and a second direction Y so as to have a predetermined size and a predetermined interval. Due to the plurality of opening portions, a sound wave (or a sound pressure) based on a vibration of the vibration apparatus 200 may not be dispersed by the plate 170, and may concentrate on the display panel 100. Thus, the loss of a vibration caused by the plate 170 may be minimized, thereby increasing a sound pressure level characteristic of a sound generated based on a vibration of the display panel 100 (or a vibration object or a vibration member). For example, the plate 170 including the plurality of openings may have a mesh shape. For example, the plate 170 including the plurality of openings may be a mesh plate.

┬he plate 170 according to an embodiment of the present disclosure may include a metal material. For example, the plate 170 may include any one or more materials of stainless steel, aluminum (Al), a magnesium (Mg), a magnesium (Mg) alloy, a magnesium-lithium (Mg—Li) alloy, and an Al alloy, but embodiments of the present disclosure are not limited thereto. Thus, the plate 170 may act as a heat plate that dissipates heat occurring in the display panel 100.

According to an embodiment of the present disclosure, the plate 170 including a metal material may reinforce a mass of the vibration apparatus 200 which is disposed at or hung from the rear surface of the display panel 100. Thus, the plate 170 may decrease a resonance frequency of the vibration apparatus 200 based on an increase in mass of the vibration apparatus 200. Therefore, the plate 170 may increase a sound characteristic and a sound pressure level characteristic of the low-pitched sound band generated based on a vibration of the vibration apparatus 200 and may enhance the flatness of a sound pressure level characteristic. For example, the flatness of the sound pressure level characteristic may be a magnitude of a deviation between a highest sound pressure level and a lowest sound pressure level. For example, the plate 170 may be referred to as a weight member, a mass member, or a sound planarization member, or the like, but embodiments of the present disclosure are not limited thereto.

FIG. 4 is a cross-sectional view illustrating a vibration member and a vibration apparatus at a rear surface of the vibration member according to an embodiment of the present disclosure.

With reference to FIG. 4, a vibration apparatus according to an embodiment of the present disclosure may include a display panel 100 and a vibration device 211 disposed at a rear surface of the display panel (or vibration member) 100.

The vibration device 211 may include a vibration portion 211a, a first electrode portion 211c disposed at a first surface or an upper surface of the vibration portion 211a, a second electrode portion 211b disposed at a second surface opposite to the first surface, a first cover member 214 disposed at the first surface of the vibration portion 211a, and a second cover member 215 disposed at the second surface of the vibration portion 211a. The vibration device 211 may include a first adhesive layer 212 and a second adhesive layer 213, which are disposed between the first cover member 214 and the second cover member 215 and surround the vibration apparatus 200. The first adhesive layer 212 may be disposed at the first surface of the vibration portion 211a and the second adhesive layer 213 may be disposed at the second surface of the vibration portion 211a.

For example, each of the first cover member 214 and the second cover member 215 may be a polyimide (PI) film or a polyethylene terephthalate (PET) film, but embodiments of the present disclosure are not limited thereto.

Each of the first and second adhesive layers 212 and 213 may include an electric insulating material. For example, the electric insulating material may have adhesiveness and may include a material capable of compression and decompression. For example, one or more of the first and second adhesive layers 212 and 213 may include an epoxy resin, an acrylic resin, a silicone resin, or a urethane resin, but embodiments of the present disclosure are not limited thereto.

The apparatus or the vibration apparatus 200 according to an embodiment of the present disclosure may further include a connection member 150 disposed between the display panel 100 and the vibration device 211. The connection member 150 may include an electric insulating material. For example, the electric insulating material may have adhesiveness and may include a material capable of compression and decompression. For example, the connection member 150 may include an epoxy resin, an acrylic resin, a silicone resin, or a urethane resin, but embodiments of the present disclosure are not limited thereto.

The vibration portion 211a may be configured as a plurality of inorganic material portions. For example, the inorganic material portions may be configured as a ceramic-based material for generating a relatively high vibration, or may be configured as a piezoelectric ceramic having a perovskite-based crystalline structure. The perovskite crystalline structure may have a piezoelectric effect and an inverse piezoelectric effect, and may be a structure of plate shape having orientation. The perovskite crystalline structure may be represented by a chemical formula “ABO₃”. In the chemical formula, “A” may include a divalent metal element, and “B” may include a tetravalent metal element. For example, in the chemical formula “ABO₃”, “A”, and “B” may be cations, and “O” may be anions.

The vibration portion 211a may be configured with a first vibration portion 211a1 and a second vibration portion 211a2, which have different physical properties. Here, the different physical properties may denote complementary physical properties. For example, the first vibration portion 211a1 may include a material having high mechanical quality factor Qm properties, and the second vibration portion 211a2 may include a material having a high piezoelectric coefficient d33. As illustrated in FIG. 4, the first vibration portion 211a1 and the second vibration portion 211a2 may be alternately arranged along a first direction X. For example, a plurality of first vibration portions 211a1 and a plurality of second vibration portions 211a2 may be alternately and repeatedly arranged along the first direction X. For example, a structure of the vibration portion 211a according to an embodiment of the present disclosure may be a structure of a stripe pattern or a chessboard structure, but embodiments of the present disclosure are not limited thereto.

The first vibration portion 211a1 may include an inorganic material portion expressed as the following Equation 1.

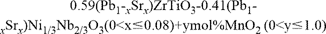

The first vibration portion 211a1 expressed as Equation 1 may include a material having a high mechanical quality factor Qm. The mechanical quality factor Qm may represent a reciprocal number of mechanical loss occurring in a vibration portion in converting energy and may be defined as loss of the vibration portion.

The second vibration portion 211a2 may include an inorganic material portion expressed as the following Equation 2.

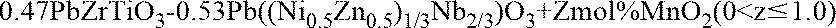

The second vibration portion 211a2 expressed as Equation 2 may include a material having a high piezoelectric constant d33. The piezoelectric constant may be defined as a deformation modulus of a piezoelectric material based on an electrical field.

The vibration apparatus 200 or the vibration device 211 according to an embodiment of the present disclosure may include a composite of a material having a high mechanical quality factor and a material having a high piezoelectric constant, and thus, mechanical strength may be enhanced. Comparing with a case where only a material having a high piezoelectric constant is used, the vibration apparatus 200 or the vibration device 211 according to an embodiment of the present disclosure may include a composite of a material having a high mechanical quality factor and a material having a high piezoelectric constant, and thus, conversion of mechanical loss may be reduced in converting electrical energy or the amount of heat may decrease, thereby preventing heat from occurring in the vibration apparatus. Also, the vibration apparatus 200 or the vibration device 211 according to an embodiment of the present disclosure may include a composite of a material having a high mechanical quality factor and a material having a high piezoelectric constant, and thus, a vibration corresponding to a low frequency may be implemented based on a piezoelectric constant and a haptic texture may be simultaneously implemented based on a high mechanical quality factor.

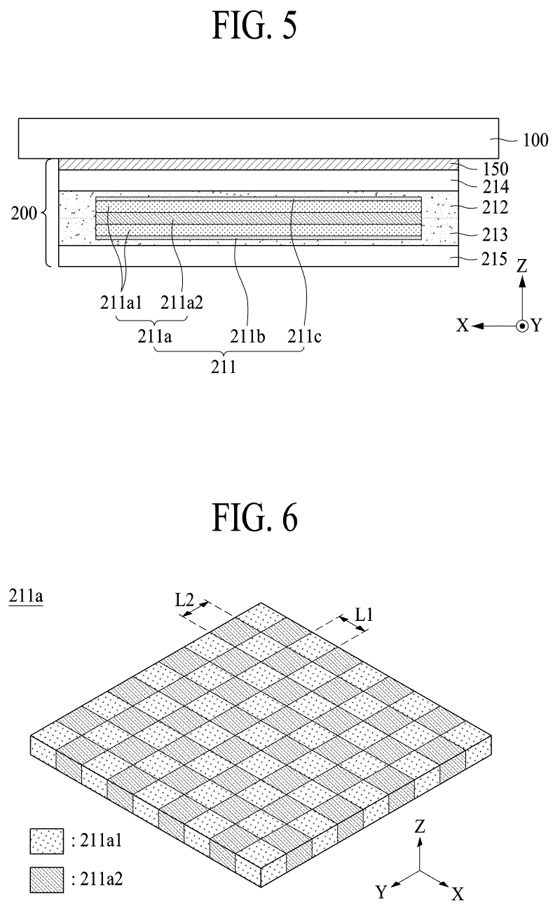

FIG. 5 is a cross-sectional view illustrating a vibration member and a vibration apparatus at a rear surface of the vibration member according to another embodiment of the present disclosure. Except for that only a structure of a vibration portion 211a is modified, a vibration apparatus of FIG. 5 may be configured identical to the vibration apparatus of FIG. 4.

With reference to FIG. 5, a vibration apparatus 200 according to an embodiment of the present disclosure may include a vibration device 211 disposed at a rear surface of the display panel 100. The vibration device 211 may include a vibration portion 211a. The vibration portion 211a of the vibration device 211 may be configured in a layer-stacked structure. For example, a first vibration portion 211a1 may be disposed adjacent to the display panel 100, a second vibration portion 211a2 may be disposed at a rear surface of the first vibration portion 211a1 subsequently, and another first vibration portion 211a1 may be disposed at a rear surface of the second vibration portion 211a2 subsequently. For example, with respect to a thickness direction Z of the vibration apparatus 200, the second vibration portion 211a2 may be disposed or interposed between the first vibration portions 211a1 and another first vibration portion 211a1. Also, each of the first vibration portion 211a1, the second vibration portion 211a2, and the first vibration portion 211a1 which are sequentially stacked may be configured to have the same thickness, but embodiments of the present disclosure are not limited thereto. According to an embodiment of the present disclosure, another first vibration portion 211a1 may be disposed at an outer portion of the first vibration portion 211a1, and thus, the durability of the first vibration portion 211a1 may be enhanced.

FIG. 6 illustrates a vibration portion according to an embodiment of the present disclosure.

With reference to FIG. 6, a vibration portion 211a according to an embodiment of the present disclosure may include a first vibration portion 211a1 and a second vibration portion 211a2. For example, a plurality of first vibration portions 211a1 and a plurality of second vibration portions 211a2 may be alternately and repeatedly disposed along a first direction X. The plurality of first vibration portions 211a1 and the plurality of second vibration portions 211a2 may be alternately and repeatedly disposed along a second direction Y. In a structure of the vibration portion 211a according to an embodiment of the present disclosure, because the plurality of first vibration portions 211a1 and the plurality of second vibration portions 211a2 are alternately disposed along the first direction X and the second direction Y, the first vibration portion 211a1 may be arranged as a type where the first vibration portion 211a1 shares a corner with another first vibration portion 211a1 closest thereto in a diagonal direction. Also, the second vibration portion 211a2 may be arranged as a type where the second vibration portion 211a2 shares a corner with another second vibration portion 211a2 closest thereto in a diagonal direction. The first vibration portion 211a1 and the second vibration portion 211a2 may have a first length L1 in the first direction X, and the first vibration portion 211a1 and the second vibration portion 211a2 may have a second length L2 in the second direction Y.

The plurality of first vibration portions 211a1 may include the same material as a piezoelectric material expressed as Equation 1 described above, and the plurality of second vibration portions 211a2 may include the same material as a piezoelectric material expressed as Equation 2 described above.

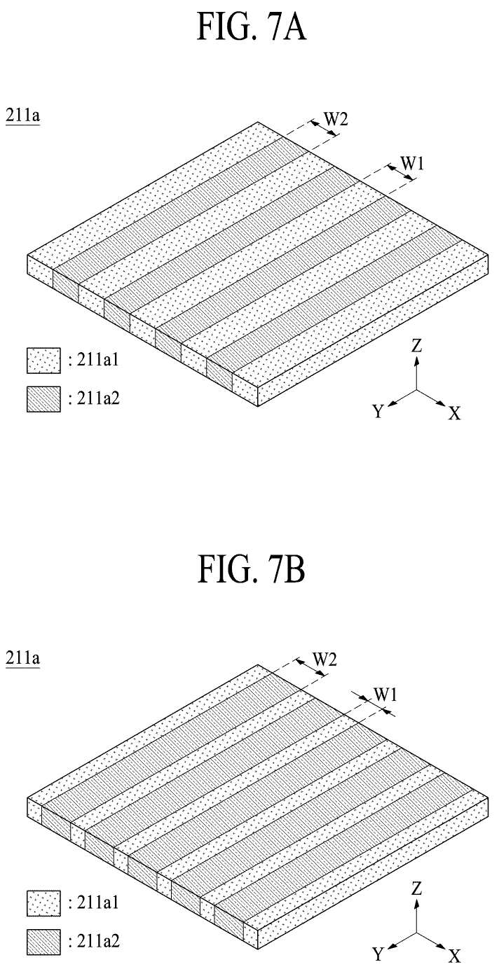

FIGS. 7A and 7B illustrate a vibration portion according to another embodiment of the present disclosure.

With reference to FIGS. 7A and 7B, a vibration portion 211a according to an embodiment of the present disclosure may include a plurality of first vibration portion 211a1 and a plurality of second vibration portion 211a2. For example, the plurality of first vibration portions 211a1 and the plurality of second vibration portions 211a2 may be alternately and repeatedly disposed along a first direction X (or a second direction Y). For example, the first direction X may be a widthwise direction of the vibration portion 211a, the second direction Y may be a lengthwise direction of the vibration portion 211a crossing the first direction X, but embodiments of the present disclosure are not limited thereto. For example, the first direction X may be the lengthwise direction of the vibration portion 211a, and the second direction Y may be the widthwise direction of the vibration portion 211a. A plurality of first vibration portions 211a1 may include the same material as a piezoelectric material expressed as Equation 1 described above. A plurality of second vibration portions 211a2 may include the same material as a piezoelectric material expressed as Equation 2 described above.

In the vibration portion 211a, each of the plurality of first vibration portion 211a1 and the plurality of second vibration portion 211a2 may be disposed (or arranged) at the same plane (or the same layer) in parallel. Each of the plurality of second vibration portion 211a2 may be configured to fill a gap between two adjacent first vibration portions of the plurality of first vibration portion 211a1 may be connected to or attached on a first vibration portion 211a1 adjacent thereto. Therefore, the vibration portion 211a may extend by a desired size or length based on the side coupling (or connection) of the first vibration portion 211a1 and the second vibration portion 211a2.

The plurality of first vibration portion 211a1 and the plurality of second vibration portion 211a2 may be alternately and repeatedly arranged along a second direction Y. Each of the plurality of first vibration portion 211a1 may be disposed between the plurality of second vibration portion 211a2. For example, each of the plurality of first vibration portion 211a1 may have a first width W1 parallel to the first direction X and a length parallel to the second direction Y. Each of the plurality of second vibration portion 211a2 may have a second width W2 parallel to the first direction X and may have a length parallel to the second direction Y. The first width W1 may be the same as or different from the second width W2. For example, the first width W1 may be the same as the second width W2. For example, the first width W1 may be the same as the second width W2 as illustrated in FIG. 7A, the first width W1 may be smaller than the second width W2 as illustrated in FIG. 7B. For example, the first vibration portion 211a1 and the second vibration portion 211a2 may include a line shape or a stripe shape which has the same size or different sizes. In the vibration portion 211a illustrated in FIGS. 7A and 7B, a width (or a size) W2 of each of the plurality of second vibration portions 211a2 may progressively decrease in a direction from a center portion to both peripheries (or both ends) of the vibration portion 211a or the vibration apparatus.

In FIGS. 7A and 7B, it is illustrated that the first vibration portion 211a1 is disposed at an outermost portion along a first direction X, but embodiments of the present disclosure are not limited thereto. Therefore, in the present disclosure, a vibration device 211 where the second vibration portion 211a2 is disposed at an outermost portion may be included in a range of the present disclosure.

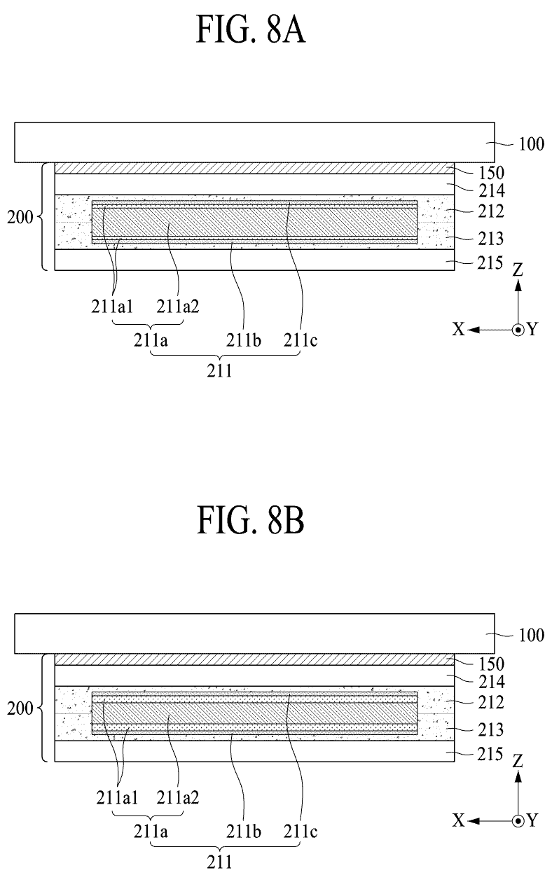

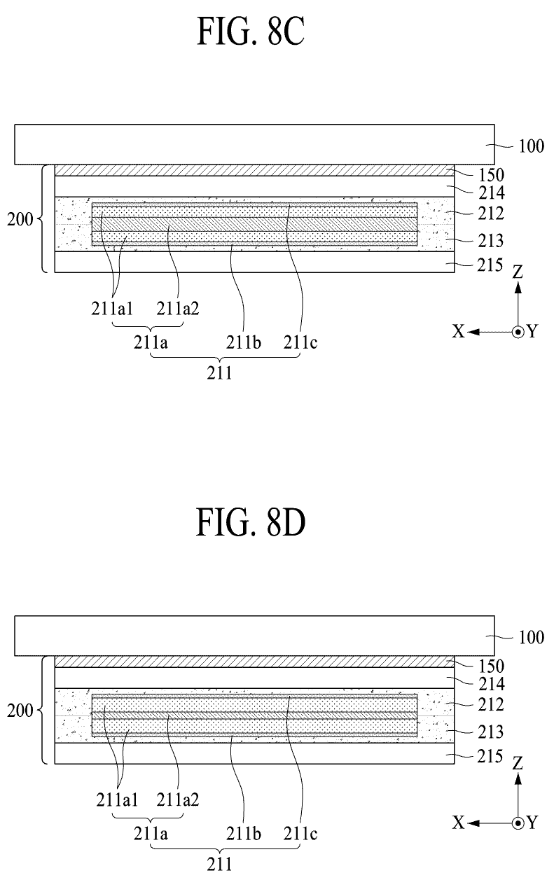

FIGS. 8A to 8D are cross-sectional views illustrating a vibration member and a vibration apparatus at a rear surface of the vibration member according to an embodiment of the present disclosure. Except for that only a structure of a vibration device 211 is modified, a vibration apparatus of FIGS. 8A to 8D may be configured identical to the vibration apparatus of FIG. 5.

With reference to FIG. 8A, in a vibration apparatus 200 according to another embodiment of the present disclosure, a vibration portion 211a of a vibration device 211 may be configured in a layer-stacked structure. For example, a first vibration portion 211a1 may be disposed adjacent to a display panel 100, a second vibration portion 211a2 may be disposed at a rear surface of the first vibration portion 211a1 subsequently, and another first vibration portion 211a1 may be disposed at a rear surface of the second vibration portion 211a2 subsequently. For example, with respect to a thickness direction Z of the vibration apparatus 200, the second vibration portion 211a2 may be disposed or interposed between the first vibration portions 211a1 and another first vibration portion 211a1. Therefore, the vibration portion 211a of FIG. 8A may be configured in a structure where the first vibration portion 211a1, the second vibration portion 211a2, and another first vibration portion 211a1 are sequentially disposed at the rear surface of the display panel 100. Each of the first vibration portions 211a1 and another first vibration portion 211a1 may be set to have a first thickness, and the second vibration portion 211a2 may be set to have a second thickness. The second thickness may be set to 8 times the first thickness. Also, a volume ratio of the first vibration portion 211a1 to the second vibration portion 211a2 with respect to all of the vibration portion 211 of FIG. 8A may be 2:8 (or 20% : 80%).

With reference to FIG. 8B, in a vibration apparatus 200 according to another embodiment of the present disclosure, a vibration portion 211a of vibration device 211 may be configured in a layer-stacked structure. For example, a first vibration portion 211a1 may be disposed adjacent to a display panel 100, a second vibration portion 211a2 may be disposed at a rear surface of the first vibration portion 211a1 subsequently, and another first vibration portion 211a1 may be disposed at a rear surface of the second vibration portion 211a2 subsequently. For example, with respect to a thickness direction Z of the vibration apparatus 200, the second vibration portion 211a2 may be disposed or interposed between the first vibration portions 211a1 and another first vibration portion 211a1. Therefore, the vibration portion 211a of FIG. 8B may be configured in a structure where the first vibration portion 211a1, the second vibration portion 211a2, and another first vibration portion 211a1 are sequentially disposed at the rear surface of the display panel 100. Each of the first vibration portions 211a1 and another first vibration portion 211a1 may be set to have a first thickness, and the second vibration portion 211a2 may be set to have a second thickness. The second thickness may be set to 1.5 times the first thickness. Also, a volume ratio of the first vibration portion 211a1 to the second vibration portion 211a2 with respect to all of the vibration portion 211 of FIG. 8B may be 4:6 (or 40% : 60%).

With reference to FIG. 8C, in a vibration apparatus 200 according to another embodiment of the present disclosure, a vibration portion 211a of vibration device 211 may be configured in a layer-stacked structure. For example, a first vibration portion 211a1 may be disposed adjacent to a display panel 100, a second vibration portion 211a2 may be disposed at a rear surface of the first vibration portion 211a1 subsequently, and another first vibration portion 211a1 may be disposed at a rear surface of the second vibration portion 211a2 subsequently. For example, with respect to a thickness direction Z of the vibration apparatus 200, the second vibration portion 211a2 may be disposed or interposed between the first vibration portions 211a1 and another first vibration portion 211a1. Therefore, the vibration portion 211a of FIG. 8C may be configured in a structure where the first vibration portion 211a1, the second vibration portion 211a2, and another first vibration portion 211a1 are sequentially disposed at the rear surface of the display panel 100. Each of the first vibration portions 211a1 may be set to have a first thickness, and the second vibration portion 211a2 may be set to have a second thickness. When the second thickness is set to a thickness of 40% of the total thickness of the vibration portion 211a, the first thickness may be set to a thickness of 30% of the total thickness of the vibration portion 211a. Also, a volume ratio of the first vibration portion 211a1 to the second vibration portion 211a2 with respect to all of the vibration portion 211 of FIG. 8C may be 6:4 (or 60% : 40%).

With reference to FIG. 8D, in a vibration apparatus 200 according to another embodiment of the present disclosure, a vibration portion 211a of a vibration device 211 may be configured in a layer-stacked structure. For example, a first vibration portion 211a1 may be disposed adjacent to a display panel 100, a second vibration portion 211a2 may be disposed at a rear surface of the first vibration portion 211a1 subsequently, and a first vibration portion 211a1 may be disposed at a rear surface of the second vibration portion 211a2 subsequently. For example, with respect to a thickness direction Z of the vibration apparatus 200, the second vibration portion 211a2 may be disposed or interposed between the first vibration portions 211a1 and another first vibration portion 211a1. Therefore, the vibration portion 211a of FIG. 8D may be configured in a structure where the first vibration portion 211a1, the second vibration portion 211a2, and another first vibration portion 211a1 are sequentially disposed at the rear surface of the display panel 100. Each of the first vibration portions 211a1 may be set to have a first thickness, and the second vibration portion 211a2 may be set to have a second thickness. The second thickness may be set to 0.5 times the first thickness. Also, a volume ratio of the first vibration portion 211a1 to the second vibration portion 211a2 with respect to all of the vibration portion 211 of FIG. 8D may be 8:2 (or 80% : 20%).

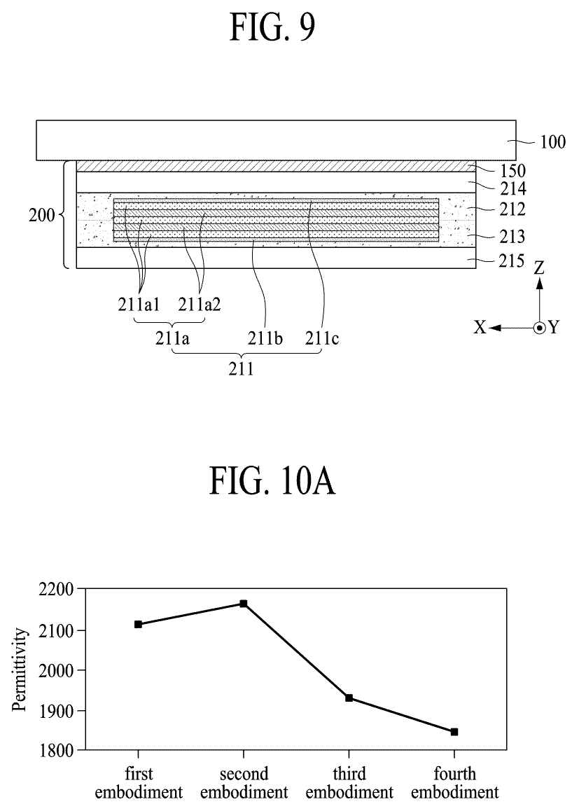

FIG. 9 is a cross-sectional view illustrating a vibration member and a vibration apparatus at a rear surface of the vibration member according to another embodiment of the present disclosure. Except for that only a structure of a vibration device 211 is modified, a vibration apparatus of FIG. 9 may be configured identical to the vibration apparatus of FIG. 5.

With reference to FIG. 9, a vibration apparatus 200 according to another embodiment of the present disclosure may include a vibration device 211 disposed at a rear surface of the display panel 100. The vibration device 211 may include a vibration portion 211a. The vibration portion 211a of the vibration device 211 may be configured in a layer-stacked structure. For example, a first vibration portion 211a1 may be disposed adjacent to a display panel 100, a second vibration portion 211a2 may be disposed at a rear surface of the first vibration portion 211a1 subsequently, another first vibration portion 211a1 may be disposed at a rear surface of the second vibration portion 211a2 subsequently, another second vibration portion 211a2 may be disposed at a rear surface of another first vibration portion 211a1 subsequently, and another first vibration portion 211a1 may be disposed at a rear surface of another second vibration portion 211a2 subsequently. Each of the first vibration portions 211a1 and each of the second vibration portions 211a2 may be configured to have the same thickness or different thicknesses. Also, each of the first vibration portion 211a1, the second vibration portion 211a2, and the first vibration portion 211a1 which are sequentially stacked may be configured to have the same thickness, but embodiments of the present disclosure are not limited thereto. According to an embodiment of the present disclosure, the first vibration portion 211a1 may be disposed at an outer portion of the first vibration portion 211a1, and thus, the durability of the first vibration portion 211a1 may be enhanced.

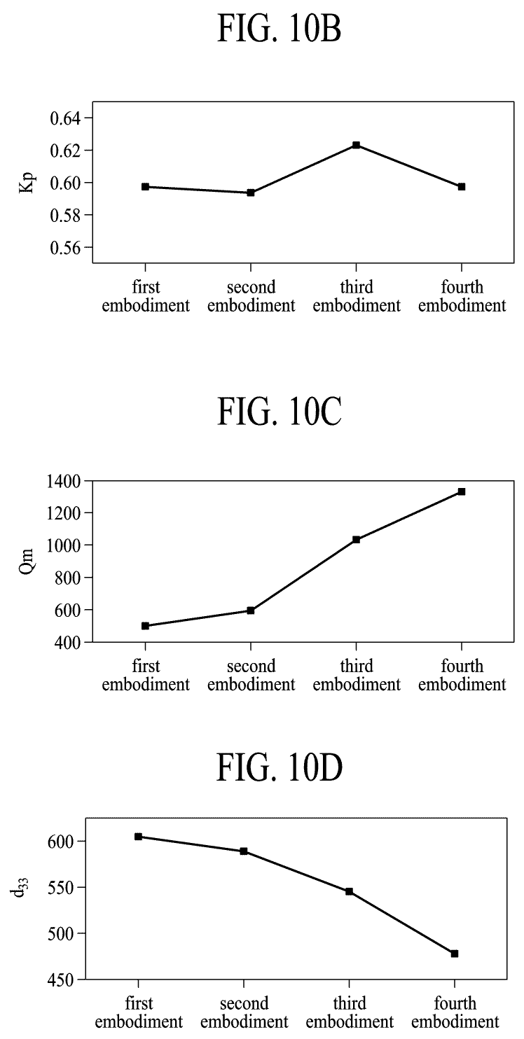

FIGS. 10A to 10D are graphs of a permittivity, an electromechanical coupling coefficient, a mechanical quality factor, and a piezoelectric constant of a vibration apparatus according to an embodiment of the present disclosure. In FIGS. 10A to 10D, a first embodiment may be a vibration apparatus prepared under a condition of FIG. 8A, a second embodiment may be a vibration apparatus prepared under a condition of FIG. 8B, a third embodiment may be a vibration apparatus prepared under a condition of FIG. 8C, and a fourth embodiment may be a vibration apparatus prepared under a condition of FIG. 8D. In each of the vibration apparatuses prepared according to the first to fourth embodiments, a permittivity, an electromechanical coupling coefficient, a mechanical quality factor, and a piezoelectric constant have been measured.

With reference to FIG. 10A, a permittivity of the vibration apparatus prepared according to the first embodiment has been measured to be about 2,100, and a permittivity of the vibration apparatus prepared according to the second embodiment has been measured to be about 2,160. A permittivity of the vibration apparatus prepared according to the third embodiment has been measured to be about 1,930, and a permittivity of the vibration apparatus prepared according to the fourth embodiment has been measured to be about 1,850. With reference to a measurement result of FIG. 10A, in the vibration portion 211a of the vibration device, it may be seen that a permittivity varies based on a variation of a relative ratio of the first vibration portion 211a1 to the second vibration portion 211a2, and for example, it may be seen that a value of a permittivity decreases when a relative ratio of the first vibration portion 211a1 increases and a value of a permittivity increases when a relative ratio of the second vibration portion 211a2 increases.

With reference to FIG. 10B, an electromechanical coupling coefficient Kp of the vibration apparatus prepared according to the first embodiment has been measured to be about 0.60, and an electromechanical coupling coefficient Kp of the vibration apparatus prepared according to the second embodiment has been measured to be about 0.60. An electromechanical coupling coefficient Kp of the vibration apparatus prepared according to the third embodiment has been measured to be about 0.625, and an electromechanical coupling coefficient Kp of the vibration apparatus prepared according to the fourth embodiment has been measured to be about 0.60. With reference to a measurement result of FIG. 10B, an electromechanical coupling coefficient may be a material constant representing energy variation efficiency and it may be seen that each of the vibration apparatuses prepared according to the first to fourth embodiments represents an electromechanical coupling coefficient close to 0.60 which is relatively high, and thus, it may be considered that a piezoelectric displacement needed for each of the vibration apparatuses prepared according to the first to fourth embodiments is satisfied to a degree.

According to an embodiment of the present disclosure, an electromechanical coupling coefficient of the vibration device may be greater than 0.59. According to an embodiment of the present disclosure, when an electromechanical coupling coefficient of the vibration device increases, the electromechanical coupling coefficient may be a material constant representing conversion efficiency from mechanical energy to electrical energy or conversion efficiency from electrical input energy to mechanical energy. Accordingly, the vibration device according to an embodiment of the present disclosure may have high energy conversion efficiency.

With reference to FIG. 10C, a mechanical quality factor Qm of the vibration apparatus prepared according to the first embodiment has been measured to be about 500, and a mechanical quality factor Qm of the vibration apparatus prepared according to the second embodiment has been measured to be about 600. A mechanical quality factor Qm of the vibration apparatus prepared according to the third embodiment has been measured to be about 1,000, and a mechanical quality factor Qm of the vibration apparatus prepared according to the fourth embodiment has been measured to be about 1,350.

With reference to a measurement result of FIG. 10C, it may be seen that a mechanical quality factor varies based on a variation of a relative ratio of the first vibration portion 211a1 to the second vibration portion 211a2 in the vibration portion 211a of the vibration device, and for example, it may be seen that a value of a mechanical quality factor increases when a relative ratio of the first vibration portion 211a1 increases, and a value of a mechanical quality factor decreases when a relative ratio of the second vibration portion 211a2 increases.

According to an embodiment of the present disclosure, a mechanical quality factor of the vibration device may be greater than 500. The vibration apparatus according to an embodiment of the present disclosure may be configured to have a high mechanical quality factor, and thus, conversion of mechanical loss may decrease in converting electrical energy and the amount of heat may decrease, thereby preventing the occurrence of heat in the vibration apparatus.

With reference to FIG. 10D, a piezoelectric coefficient d33 of the vibration apparatus prepared according to the first embodiment has been measured to be about 610, and a piezoelectric coefficient d33 of the vibration apparatus prepared according to the second embodiment has been measured to be about 585. A piezoelectric coefficient d33 of the vibration apparatus prepared according to the third embodiment has been measured to be about 540, and a piezoelectric coefficient d33 of the vibration apparatus prepared according to the fourth embodiment has been measured to be about 475. With reference to a measurement result of FIG. 10D, it may be seen that a piezoelectric coefficient varies based on a variation of a relative ratio of the first vibration portion 211a1 to the second vibration portion 211a2 in the vibration portion 211a of the vibration device, and for example, it may be seen that a value of a piezoelectric coefficient decreases when a relative ratio of the first vibration portion 211a1 increases, and a value of a piezoelectric coefficient increases when a relative ratio of the second vibration portion 211a2 increases. Based on a result of FIG. 10D, it may be seen that a value of a piezoelectric constant of the vibration apparatus according to an embodiment of the present disclosure is measured in proportion to a volume of the second vibration portion 211a2 to a degree.

According to an embodiment of the present disclosure, a piezoelectric constant of the vibration device may be greater than 450. In the present disclosure, when a piezoelectric constant of the vibration device increases, haptic driving for implementing a low frequency texture within a frequency range of a low frequency vibration may be performed. Also, a low frequency vibration value of the present disclosure may have a value proportional to a piezoelectric constant.

Table 1 may show a low frequency vibration and a vibration displacement of an embodiment of the present disclosure. In Table 1, a low frequency vibration and a vibration displacement of each of the vibration apparatuses prepared according to the first to fourth embodiments have been measured. In Table 1, the low frequency vibration may represent a result obtained by measuring an acceleration of each of the first to fourth embodiments within a frequency range of the low frequency vibration, and the vibration displacement may represent a maximum displacement value of each of the vibration apparatuses prepared according to the first to fourth embodiments. In Table 1, the first embodiment may be the vibration apparatus prepared under the condition of FIG. 8A, the second embodiment may be the vibration apparatus prepared under the condition of FIG. 8B, the third embodiment may be the vibration apparatus prepared under the condition of FIG. 8C, and the fourth embodiment may be the vibration apparatus prepared under the condition of FIG. 8D. In Table 1, a low frequency vibration frequency range may be a range of 200 Hz (hertz) to 250 Hz which is a frequency range for implementing a haptic feedback and transferring the haptic feedback to a user, and for example, the low frequency vibration frequency range may be a frequency range of a frequency band of 1 Hz to 250 Hz, but the low frequency vibration frequency range of the present disclosure is not limited thereto. Also, in Table 1, a vibration displacement or a piezoelectric displacement may have a value obtained by measuring a maximum displacement in a certain selected frequency.

TABLE 1

| | | | | |
|---|---|---|---|---|
| | First Embodiment | Second Embodiment | Third Embodiment | Fourth Embodiment |
| Low Frequency Vibration | 1.8 G | 1.6 G | 1.6 G | 1.5 G |
| Vibration | 1.2 µm | 1.5 µm | 2.1 µm | 2.3 µm |
| Displacement | | | | |

With reference to Table 1, it may be seen that the low frequency vibration represents a value of 1.5 G to 1.8 G in the first to fourth embodiments, and thus, it may be seen that the vibration apparatus prepared according to an embodiment of the present disclosure is capable of being haptic-driven for implementing a low frequency texture within a frequency range of the low frequency vibration. Also, with reference to the low frequency vibration measurement value of Table 1 and a value of the piezoelectric constant of FIG. 10D, it may be seen that the low frequency vibration value of the present disclosure has a value proportional to a piezoelectric constant to a degree.

Moreover, the vibration displacement has been measured to be a value of 1.2 µm in the first embodiment and has been measured to be a value of 1.5 µm in the second embodiment. The vibration displacement has been measured to be a value of 2.1 µm in the third embodiment and has been measured to be a value of 2.3 µm in the fourth embodiment. With reference to the vibration displacement measurement value of Table 1 and a value of the mechanical quality factor of FIG. 10C, it may be seen that the vibration displacement measurement value of the present disclosure has a value proportional to a mechanical quality factor to a degree.

A vibration apparatus according to an embodiment of the present disclosure may be applied to a vibration apparatus disposed in an apparatus. The apparatus according to an embodiment of the present disclosure may be applied to mobile apparatuses, video phones, smart watches, watch phones, wearable apparatuses, foldable apparatuses, rollable apparatuses, bendable apparatuses, flexible apparatuses, curved apparatuses, sliding apparatuses, variable apparatuses, electronic organizers, electronic book, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theater apparatuses, theater display apparatuses, TVs, wall paper display apparatuses, signage apparatuses, game apparatuses, notebook computers, monitors, cameras, camcorders, home appliances, etc. Addition, the vibration apparatus according to an embodiment of the present disclosure may be applied to organic light emitting lighting apparatuses or inorganic light emitting lighting apparatuses. When the vibration apparatus of an embodiment of the present disclosure is applied to lighting apparatuses, the lighting apparatus may act as lighting and a speaker. Addition, when the vibration apparatus of an embodiment of the present disclosure is applied to a mobile device, or the like, the vibration apparatus may act as one or more of a speaker, a receiver, and a haptic, but embodiments of the present disclosure are not limited thereto.

A vibration apparatus and an apparatus including the same according to an embodiment of the present disclosure will be described below.

A vibration apparatus according to an embodiment of the present disclosure may comprise a first vibration portion including a first material, and a second vibration portion disposed adjacent to the first vibration portion, the second vibration portion including a second material.

According to some embodiments of the present disclosure, the first vibration portion and the second vibration portion may be alternately disposed horizontally.

According to an embodiment of the present disclosure, the first vibration portion or the second vibration portion may share a corner adjacent thereto in a diagonal direction of a plane.

According to some embodiments of the present disclosure, the first vibration portion and the second vibration portion may be alternately disposed along a first direction, wherein the first direction may be a widthwise direction or a lengthwise direction of the vibration portion.

According to some embodiments of the present disclosure, the first vibration portion and the second vibration portion may be alternately disposed along the first direction and may be alternately disposed along a second direction, wherein the second direction crosses the first direction.

According to an embodiment of the present disclosure, the first vibration portion may share a corner with another first vibration portion adjacent thereto in a diagonal direction of a plane and/or the second vibration portion may share a corner with another second vibration portion adjacent thereto in a diagonal direction of a plane.

According to some embodiments of the present disclosure, the first vibration portion and the second vibration portion may be disposed in a layer-stacked structure.

According to some embodiments of the present disclosure, the vibration apparatus may further comprise another first vibration portion including the first material, the first vibration portion is disposed adjacent to a rear surface of a vibration member, the second vibration portion is disposed at a rear surface of the first vibration portion, and another first vibration portion is disposed at a rear surface of the second vibration portion.

According to some embodiments of the present disclosure, the first vibration portion may be expressed as Equation 1, and the second vibration portion may be expressed as Equation 2.

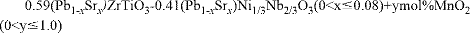

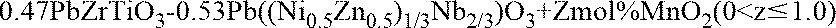

According to some embodiments of the present disclosure, the vibration apparatus may further comprise a first electrode portion and a second electrode portion, wherein each of the first vibration portion and the second vibration portion is disposed between the first electrode portion and the second electrode portion.

According to some embodiments of the present disclosure, the vibration apparatus may further comprise a vibration device, the vibration device may include a vibration portion including the first vibration portion and the second vibration portion, a first electrode portion disposed at a first surface of the vibration portion, and a second electrode portion disposed at a second surface opposite to the first surface of the vibration portion.

According to some embodiments of the present disclosure, a mechanical quality factor of the vibration apparatus may be greater than 500.

According to some embodiments of the present disclosure, an electromechanical coupling coefficient of the vibration apparatus may be greater than 0.59.

According to some embodiments of the present disclosure, a piezoelectric constant of the vibration apparatus may be greater than 450.

A vibration apparatus according to an embodiment of the present disclosure may comprise: a vibration portion including a first vibration portion and a second vibration portion; a first electrode portion disposed at a first surface of the vibration portion; and a second electrode portion disposed at a second surface opposite to the first surface of the vibration portion, wherein the first vibration portion includes a first material, the second vibration portion includes a second material, and the second vibration portion is disposed adjacent to the first vibration portion.

According to some embodiments of the present disclosure, the first vibration portion and the second vibration portion may be alternately disposed horizontally.

According to some embodiments of the present disclosure, the vibration portion may further include another first vibration portion including the first material, wherein the first vibration portion is disposed adjacent to a rear surface of a vibration member, wherein the second vibration portion is disposed at a rear surface of the first vibration portion, and wherein another first vibration portion is disposed at a rear surface of the second vibration portion.

According to some embodiments of the present disclosure, the vibration apparatus may further comprise: a first cover member disposed at the first surface of the vibration portion, and a second cover member disposed at the second surface of the vibration portion; and a first adhesive layer disposed at the first surface of the vibration portion, and a second adhesive layer disposed at the second surface of the vibration portion, wherein each of the first adhesive layer and the second adhesive layer is disposed between the first cover member and the second cover member, and a combination of the first adhesive layer and the second adhesive layer surrounds the vibration portion, the first electrode portion and the second electrode portion.

According to some embodiments of the present disclosure, the apparatus may comprise a vibration object, a vibration generating apparatus at the vibration object, and a connection member between the vibration object and the vibration generating apparatus, the vibration generating apparatus may comprise one or more vibration apparatus, the one or more vibration apparatus may comprise a first vibration portion including a first material, and a second vibration portion disposed adjacent to the first vibration portion, the second vibration portion including a second material.

According to some embodiments of the present disclosure, the vibration object may be a display panel including pixels configured to display an image, the display panel may include a first rear region and a second rear region, and the vibration generating apparatus may comprise a first vibration generating apparatus disposed at the first rear region, and a second vibration generating apparatus disposed at the second rear region.

According to some embodiments of the present disclosure, the apparatus may further comprise a plate between the display panel and the vibration generating apparatus.

According to some embodiments of the present disclosure, the vibration object may comprise one or more among a display panel including a pixel configured to display an image, a screen panel on which an image is to be projected from a display apparatus, a lighting panel, a signage panel, a vehicular interior material, a vehicular glass window, a vehicular exterior material, a building ceiling material, a building interior material, a building glass window, an aircraft interior material, an aircraft glass window, wood, plastic, glass, metal, cloth, fiber, paper, rubber, leather, carbon, and a mirror.

It will be apparent to those skilled in the art that various modifications and variations can be made in the vibration apparatus and the apparatus including the same of the present disclosure without departing from the technical idea or scope of the disclosures. Thus, it is intended that the present disclosure covers the modifications and variations of this disclosure provided they come within the scope of the appended claims and their equivalents.

What is claimed is:

1. A vibration apparatus, comprising:
a first vibration portion including a first material; and
a second vibration portion disposed adjacent to the first vibration portion, the second vibration portion including a second material.

2. The vibration apparatus of claim 1, wherein the first vibration portion and the second vibration portion are alternately disposed horizontally.

3. The vibration apparatus of claim 2, wherein the first vibration portion shares a corner with another first vibration portion adjacent thereto in a diagonal direction of a plane and/or the second vibration portion shares a corner with another second vibration portion adjacent thereto in a diagonal direction of a plane.

4. The vibration apparatus of claim 1, further comprising another first vibration portion including the first material,
wherein the first vibration portion is disposed adjacent to a rear surface of a vibration member,
wherein the second vibration portion is disposed at a rear surface of the first vibration portion, and
wherein another first vibration portion is disposed at a rear surface of the second vibration portion.

5. The vibration apparatus of claim 1, wherein the first vibration portion is expressed as Equation 1, and the second vibration portion is expressed as Equation 2.
$$\begin{matrix}0.59 \left({\text{Pb}}_{1 \text{-x}} {\text{Sr}}_{\text{x}}\right) {\text{ZrTiO}}_{3} \text{-0} \text{.41} \left({\text{Pb}}_{1 \text{-x}} {\text{Sr}}_{\text{x}}\right) {\text{Ni}}_{1 \text{/3}} {\text{Nb}}_{\text{⅔}} {\text{O}}_{\text{3}} \left(\text{0<x} \text{} \leq \text{} 0.08\right) + \\ {\text{ymol\%MnO}}_{2} \left(\text{0<y} \text{} \leq \text{} \text{1} \text{.0}\right)\end{matrix}$$
$$\begin{matrix}0.47 {\text{PbZrTiO}}_{3} \text{-0} \text{.53Pb} \left({\left({\text{Ni}}_{0.5} {\text{Zn}}_{0.5}\right)}_{1 / 3} {\text{Nb}}_{2 / 3}\right) {\text{O}}_{3} \text{+} \\ {\text{Zmol\%MnO}}_{2} \left(\text{0<z} \text{} \leq \text{} \text{1} \text{.0}\right)\end{matrix}$$
.

6. The vibration apparatus of claim 1, further comprising:
a first electrode portion, and
a second electrode portion,
wherein each of the first vibration portion and the second vibration portion is disposed between the first electrode portion and the second electrode portion.

7. The vibration apparatus of claim 6, wherein a mechanical quality factor of the vibration apparatus is greater than 500.

8. The vibration apparatus of claim 6, wherein an electromechanical coupling coefficient of the vibration apparatus is greater than 0.59.

9. The vibration apparatus of claim 6, wherein a piezoelectric constant of the vibration apparatus is greater than 450.

10. A vibration apparatus, comprising:
a vibration portion including a first vibration portion and a second vibration portion;
a first electrode portion disposed at a first surface of the vibration portion; and
a second electrode portion disposed at a second surface opposite to the first surface of the vibration portion,
wherein the first vibration portion includes a first material, the second vibration portion includes a second material, and the second vibration portion is disposed adjacent to the first vibration portion.

11. The vibration apparatus of claim 10, wherein the first vibration portion and the second vibration portion are alternately disposed horizontally.

12. The vibration apparatus of claim 10, wherein the vibration portion further includes another first vibration portion including the first material,
wherein the first vibration portion is disposed adjacent to a rear surface of a vibration member,
wherein the second vibration portion is disposed at a rear surface of the first vibration portion, and
wherein another first vibration portion is disposed at a rear surface of the second vibration portion.

13. The vibration apparatus of claim 10, further comprising:
a first cover member disposed at the first surface of the vibration portion, and a second cover member disposed at the second surface of the vibration portion; and
a first adhesive layer disposed at the first surface of the vibration portion, and a second adhesive layer disposed at the second surface of the vibration portion,
wherein each of the first adhesive layer and the second adhesive layer is disposed between the first cover member and the second cover member, and a combination of the first adhesive layer and the second adhesive layer surrounds the vibration portion, the first electrode portion and the second electrode portion.

14. An apparatus, comprising:
a vibration object;
a vibration generating apparatus at the vibration object; and
a connection member between the vibration object and the vibration generating apparatus,
wherein the vibration generating apparatus comprises one or more vibration apparatus of claim 1.

15. The apparatus of claim 14, wherein:
the vibration object is a display panel including pixels configured to display an image,
the display panel includes a first rear region and a second rear region, and
the vibration generating apparatus comprises:
a first vibration generating apparatus disposed at the first rear region; and
a second vibration generating apparatus disposed at the second rear region.

16. The apparatus of claim 14, further comprising a plate between the display panel and the vibration generating apparatus.

17. The apparatus of claim 14, wherein the vibration object comprises one or more among a display panel including a pixel configured to display an image, a screen panel on which an image is to be projected from a display apparatus, a lighting panel, a signage panel, a vehicular interior material, a vehicular glass window, a vehicular exterior material, a building ceiling material, a building interior material, a building glass window, an aircraft interior material, an aircraft glass window, wood, plastic, glass, metal, cloth, fiber, paper, rubber, leather, carbon, and a mirror.
